(19) United States
(12) Patent Application Publication
(10) Pub. No.: US 2019/0074244 A1
(43) Pub. Date: Mar. 7, 2019

(54) CIRCUIT ASSEMBLY AND METHOD FOR MANUFACTURING SAME

(71) Applicants: AutoNetworks Technologies, Ltd., Yokkaichi, Mie (JP); Sumitomo Wiring Systems, Ltd., Yokkaichi, Mie (JP); SUMITOMO ELECTRIC INDUSTRIES, LTD., Osaka-shi, Osaka (JP)

(72) Inventors: Arinobu Nakamura, Yokkaichi, Mie (JP); Tou Chin, Yokkaichi, Mie (JP)

(21) Appl. No.: 15/759,332

(22) PCT Filed: Aug. 31, 2016
(86) PCT No.: PCT/JP2016/075429

§ 371 Date: Mar. 12, 2018

(30) Foreign Application Priority Data
Sep. 14, 2015 (JP) 2015-180301

(51) Int. Cl. H01L 23/498; H01L 21/48; H01L 23/538; H01L 25/07

(52) U.S. Cl. CPC H01L 23/49805; H01L 21/4853; H01L 25/072; H01L 23/49838; H01L 23/5384

(57) ABSTRACT

A circuit assembly that can be made small and a method for manufacturing the same are provided. A circuit assembly includes a substrate provided with a wiring pattern on one side, and a conductive member fixed to the other side of the substrate, and if portions (terminal portions) that are to be connected to an external electrical element are formed in the conductive member, the conductive member overlaps with the substrate, but not at the portions (terminal portions). A configuration may also be adopted in which the entire conductive member overlaps with the substrate.

### CROSS-REFERENCE TO RELATED APPLICATIONS

This application is the U.S. national stage of PCT/JP2016/075429 filed Aug. 31, 2016, which claims priority of Japanese Patent Application No. JP 2015-180301 filed Sep. 14, 2015.

### TECHNICAL FIELD

The present invention relates to a circuit assembly including a substrate and a conductive member, and a method for manufacturing the same.

### BACKGROUND

Circuit assemblies obtained by providing a wiring pattern on one side of a substrate and fixing a plate-shaped conductive member (also referred to as “bus bar” or the like) to the other side of the substrate are known (for example, see JP 2003-164040A below).

In the circuit assembly disclosed in JP 2003-164040A above, the conductive member is ultimately divided into a plurality of elements (a plurality of pieces). Specifically, after the conductive member in which these elements are linked by an outer frame is connected to the substrate, this outer frame is removed (see the change from FIG. 7 to FIG. 8 in JP 2003-164040A). That is, the outer frame is separated therefrom and it is difficult to cut sites located inward of an outer edge of the substrate, and thus, sites located outward of the outer edge of the substrate are cut (see e.g. paragraph [0055] in JP 2003-164040M. Therefore, portions that were joined to the outer frame (which is a functionally unnecessary portion) protrude from the outer edge of the substrate.

An issue resolved by the present invention is to provide a circuit assembly that can be made small and a method for manufacturing the same.

### SUMMARY

A circuit assembly according to the present invention made in order to resolve the above-described issue includes a substrate provided with a wiring pattern on one side of the substrate, a conductive member fixed to the other side of the substrate, and an electronic component having a plurality of terminals that are electrically connected to either the conductive member or the wiring pattern that is formed on the substrate. The conductive member overlaps with the substrate, but not at a portion that is to be connected to an external electrical element.

The circuit assembly according to the present invention has a structure in which portions other than the portion that is connected to the external electrical element is located inward of the outer edge of the substrate, and thus the circuit assembly can be made smaller than a conventional circuit assembly (can reduce a space).

The conductive member may include a first conductor and a second conductor that are fixed to the other side of the substrate in a separated state, and the electronic component may include a first terminal that is electrically connected to the first conductor of the conductive member, a second terminal that is electrically connected to the second conductor of the conductive member, and a third terminal that is electrically connected to the wiring pattern formed on the substrate.

The conductive member can have the first conductor and the second conductor that are separated from each other and to which various terminals (the first terminal and the second terminal) of the electronic component are connected. The first conductor and the second conductor that are separated from each other can also be fixed to the substrate simultaneously (in the same step).

The other side of the substrate may be provided with a terminal connection portion that is joined to the wiring pattern such that the terminal connection portion does not overlap with the conductive member, and the third terminal of the electronic component may be electrically connected to the terminal connection portion via a lead member.

The third terminal of the electronic component can be electrically connected to the wiring pattern via the lead member. The lead member can be fixed to the substrate together with the first conductor and the second conductor (in the same step).

It is preferable that the substrate is provided with an external connection means for electrically connecting the conductive member to an external electrical element, the conductive member is provided with an electrical connection portion that is electrically connected to the external connection means, and the entire conductive member may overlap with the substrate.

If the external connection means to which the conductive member is electrically connected is provided in a substrate, the conductive member can be connected to an external electrical element through this external connection means, and thus a configuration is possible in which the entire conductive member overlaps with the substrate.

It is preferable that the conductive member is provided with a mechanical connection portion that is fixed to the substrate, in addition to the electrical connection portion.

A mechanical connection portion for fixing the conductive member to a substrate can be provided in the conductive member. The mechanical connection portion can be connected in the same step of connecting the electrical connection portion.

A method for manufacturing a circuit assembly according to the present invention made in order to resolve the above-described issue includes a conductive member connection step of fixing a conductive member to a substrate, the substrate being provided with a wiring pattern on one side of the substrate and being provided with an insulating layer on the other side, and the conductive member being fixed such that the conductive member overlaps with the substrate, but not at a portion that is to be connected to an external electrical element, and an electronic component mounting step of mounting an electronic component having a plurality of terminals, electrically connecting at least one of the plurality of terminals to the wiring pattern of the substrate, and electrically connecting at least another of the terminals to the conductive member.

According to the method for manufacturing a circuit assembly according to the present invention, it is possible to easily manufacture a circuit assembly that can be made small. Also, a step for electrically connecting at least one terminals of an electronic component to a wiring pattern and a step for connecting at least another of the terminals to a conductive member can be collectively performed in the same step.

It is preferable that in the conductive member connection step, a first conductor and a second conductor that constitute the conductive member are fixed to the other side of the substrate in a separated state, and in the electronic component mounting step, a first terminal of the electronic component is electrically connected to the first conductor, a second terminal of the electronic component is electrically connected to the second conductor, and a third terminal of the electronic component is electrically connected to the wiring pattern formed on the substrate.

In the conductive member connection step, the first conductor and the second conductor that are separate from each other can be fixed to the substrate in the same step. Also, a step for electrically connecting the first terminal of the electronic component to the first conductor, electrically connecting the second terminal to the second conductor, and electrically connecting the third terminal to the wiring pattern can be performed in the same step.

It is preferable that the other side of the substrate is provided with a terminal connection portion that is joined to the wiring pattern, a lead member connection step of connecting a lead member to the terminal connection portion on the other side of the substrate is included, the conductive member connection step and the lead member connection step being performed simultaneously, and in the electronic component mounting step, the third terminal of the electronic component is connected to the lead member.

The step of fixing a conductive member to a substrate and the step of connecting the lead member to the substrate can be performed in the same step. If such a lead member is used, in the above-described electronic component mounting step, the third terminal of the electronic component is connected to the lead member.

### Advantageous Effects of Invention

According to the present invention, the size of the circuit assembly can be reduced.

### BRIEF DESCRIPTION OF DRAWINGS

FIG. 1(a) is a plan view of a circuit assembly (a diagram of a substrate viewed from one side) according to one embodiment of the present invention.

FIG. 1(b) is a bottom view of a circuit assembly (a diagram viewed from the conductive member side) according to one embodiment of the present invention.

FIG. 2 is an enlarged perspective view of a portion of the circuit assembly on which an electronic component is mounted.

FIG. 3 is an enlarged plan view (a diagram of the substrate viewed from one side) of the portion of the circuit assembly on which the electronic component is mounted.

FIG. 4 is an enlarged bottom view (a diagram viewed from the conductive member side) of the portion of the circuit assembly on which the electronic component is mounted.

FIG. 5(a) is a diagram schematically showing a cross-section taken along a line B-B in FIG. 3.

FIG. 5(b) is a diagram schematically showing a cross-section taken along a line C-C in FIG. 3.

FIG. 6 is a diagram schematically showing a cross-section (cross-section taken along a line A-A in FIG. 1(b)) at a site at which an electrical connection portion and an external connection portion are connected to each other.

FIG. 7 is a diagram showing the other side of a substrate.

FIG. 8(a) is a diagram showing a state in which a conductive member (a first conductor and a second conductor) are placed on the other side of the substrate.

FIG. 8(b) is a diagram showing a state in which a lead member is further placed thereon.

FIG. 9 is a diagram showing a state in which the conductive members (the first conductor and the second conductor) placed on the other side of the substrate and the lead member are connected to the other side of the substrate.

FIG. 10(a) is a plan view of a combination of the substrate, the conductive member, and the lead member shown in FIG. 9 viewed from the one side of the substrate

FIG. 10(b) is a diagram showing a state in which the electronic component is placed on the lead member together with the conductive member through an opening formed in the substrate.

FIG. 11 is a diagram showing a circuit assembly according to a modification (at least one of the terminal portions of the conductive member is located outward of the outer edge of the substrate).

### DETAILED DESCRIPTION OF PREFERRED EMBODIMENTS

Hereinafter, an embodiment of the present invention will be described in detail with reference to the drawings. Note that unless indicated otherwise, “surface direction” in the description below refers to a direction along a substrate 10 and conductive members 20, which are plate-shaped members, and “height direction” refers to a direction orthogonal to the surface direction. Note that these directions do no limit a direction in which a circuit assembly 1 is installed.

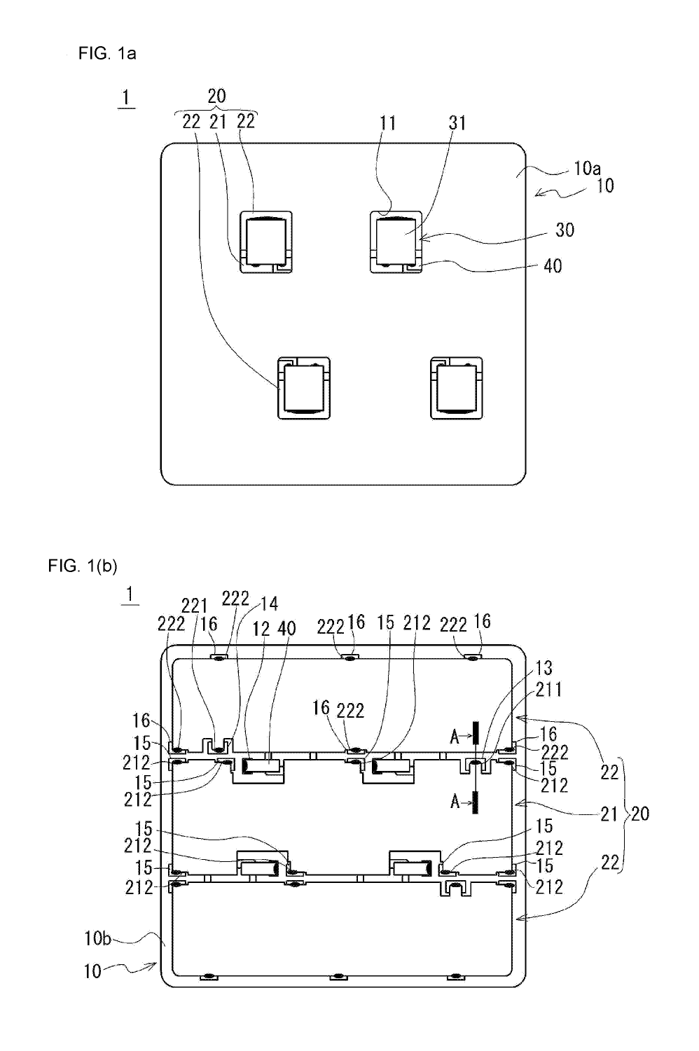

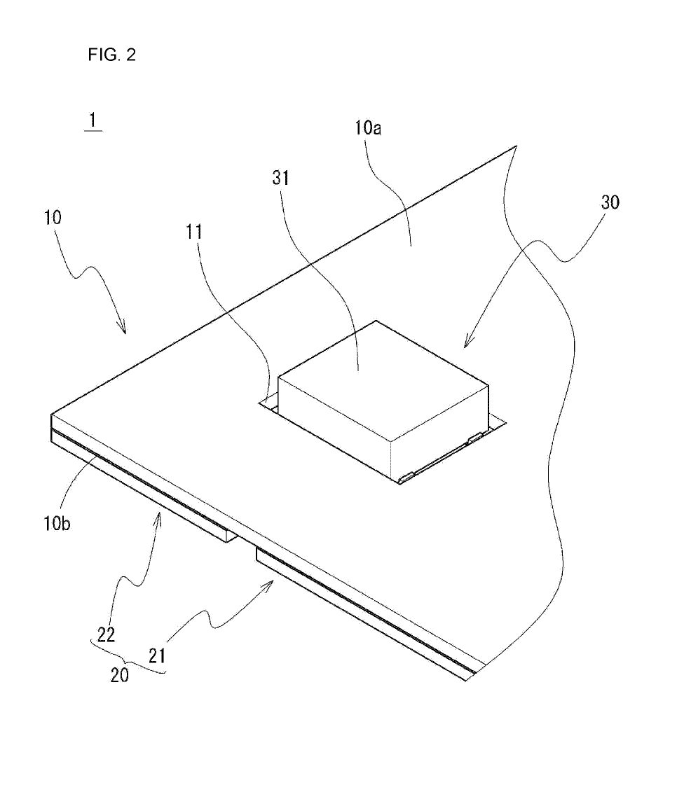

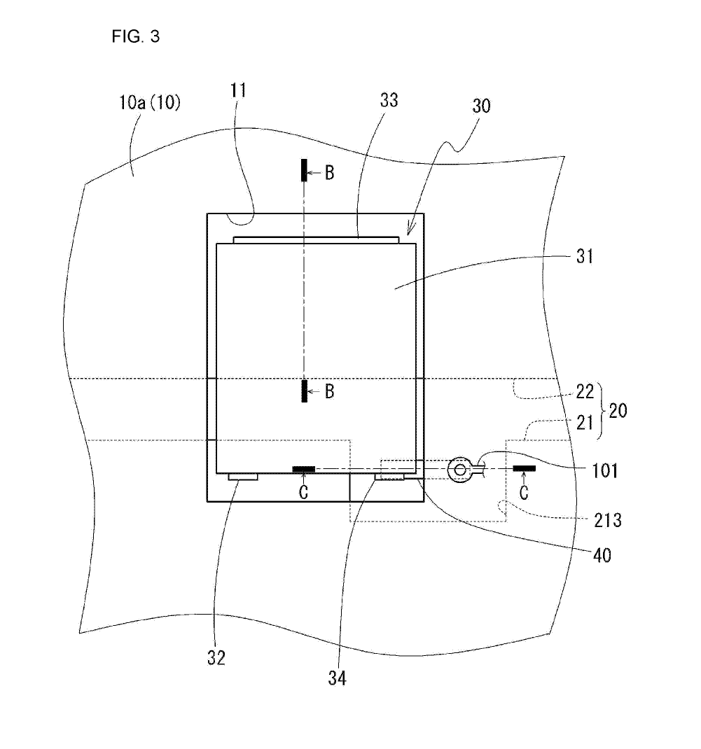

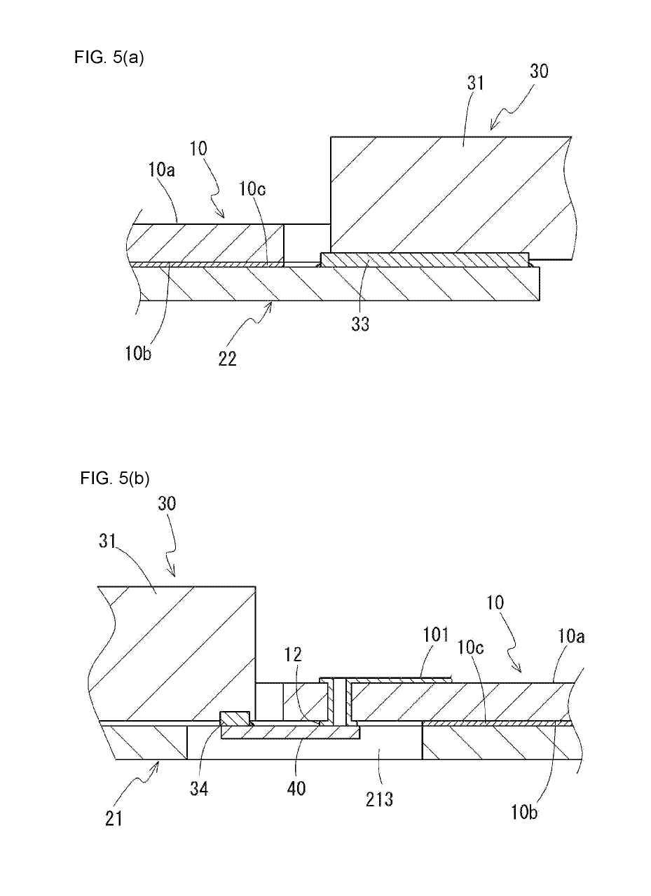

The circuit assembly 1 according to one embodiment of the present invention will be described with reference to FIGS. 1 to 6. The circuit assembly 1 according to the present embodiment includes the substrate 10, the conductive members 20, and electronic components 30. The substrate 10 is provided on one side 10a (upper surface side) with a wiring pattern 101 (for easy understanding of the diagrams, only a portion of the wiring pattern is depicted in FIGS. 3 and 5 and the wiring pattern is omitted in the other diagrams) made of a conductive thin film. A conductive path constituted by this wiring pattern 101 constitutes a circuit for control signals.

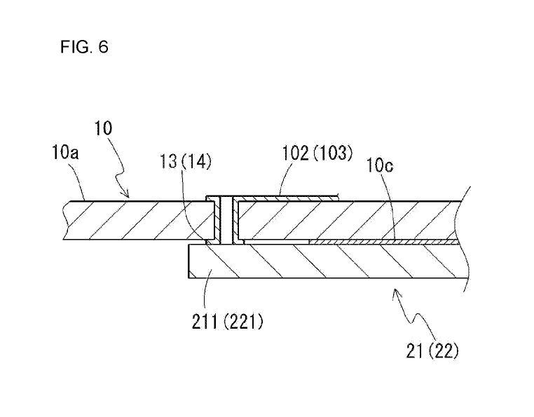

The conductive members 20 are plate-shaped portions fixed to the other side 10b (lower surface side) of the substrate 10. The conductive members 20 are formed into a predetermined shape by pressing or the like. The conductive members 20 are also referred to as “bus bars” (bus bar plates) or the like. The conductive members 20 constitute a circuit that is different from (electrically independent of) the circuit constituted by the above-described wiring pattern 101. The conductive members 20 are fixed to the other side 10b of the substrate 10 via an insulating layer (see FIGS. 5, 6, for example). Although the insulating layer is a solder resist (simply referred to as “resist 10c” hereinafter) in the present embodiment, an insulating adhesive, sheet, or the like may also be used. The insulating layer is formed at a site other than those sites at which the substrate 10 (electrical elements provided on the substrate) and the conductive members 20 are to be electrically connected to each other.

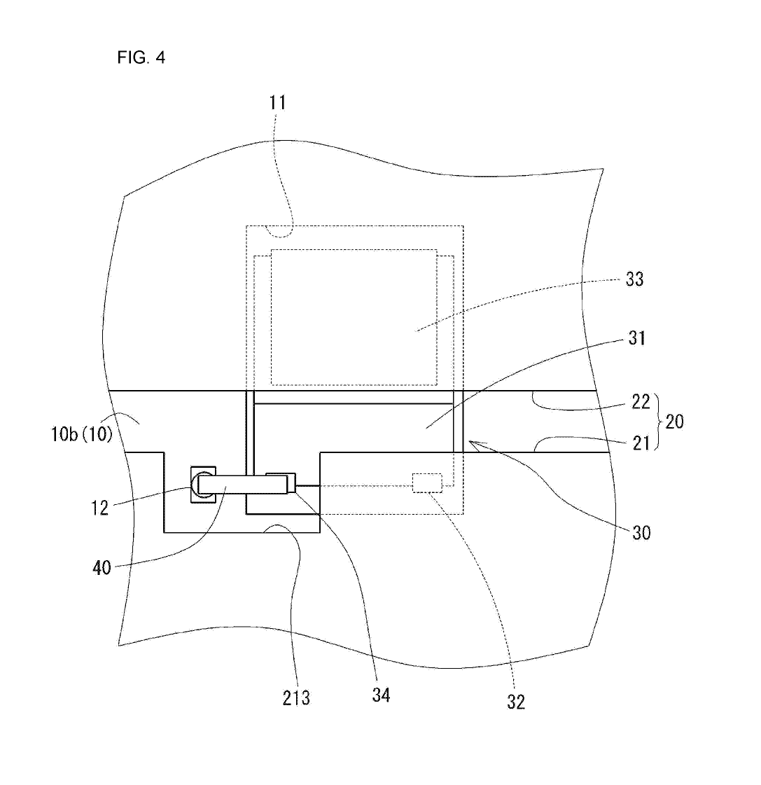

The electronic component 30 is an element that is mounted on the substrate 10, and has a main body 31 and a plurality of terminals. The terminals of the electronic component 30 in the present embodiment can be classified into terminals that are electrically connected to the conductive member 20 and a terminal that is electrically connected to the wiring pattern 101 formed on the substrate 10. More specifically, the terminals can be classified into a terminal that is electrically connected to a first conductor 21 of the conductive member 20 and a terminal that is electrically connected to a second conductor 22 of the conductive member 20, and a terminal that is electrically connected to the wiring pattern 101 formed on the substrate 10. Hereinafter, the terminal that is electrically connected to the first conductor 21 is referred to as “first terminals 32”, the terminal that is electrically connected to the second conductor 22 is referred to as “second terminal 33”, and the terminal that is electrically connected to the wiring pattern 101 formed on the substrate 10 is referred to as “third terminal 34” (see FIGS. 3, 4, for example).

An example of the electronic component 30 is a transistor (FET). In this case, a source terminal corresponds to the first terminal 32, a drain terminal corresponds to the second terminal 33, and a gate terminal corresponds to the third terminal 34. A source terminal, which is the first terminal 32, and a gate terminal, which is the third terminal 34, are located on one side of the transistor (FET), which is the electronic component 30 of the present embodiment, and a drain terminal, which is the second terminal 33, is located on the opposite side. The terminals are located below the main body 31. Specifically, part of terminals are exposed from the bottom surface of the main body 31.

Note that for easy understanding of the description, it is assumed that the electronic component 30 in the description below has one first terminal 32, one second terminal 33, and one third terminal 34. However, the number of terminals of each type included in the electronic component 30 need not be one. Also, an electronic component 30 (element) other than a transistor may also be mounted on the substrate 10.

The conductive member 20 in the present embodiment includes the first conductor 21 and the second conductors 22 that are fixed to the substrate 10 in a separated state (see FIGS. 1 to 4 for example). That is, the first conductor 21 and the second conductors 22 are not directly electrically connected to each other. Also, the first conductor 21 and the second conductors 22 are not directly mechanically connected to each other (although they are mechanically connected via the substrate 10). As will be described later in detail, the first terminal 32 (the source terminal if the electronic component 30 is a FET) of the electronic component 30 is electrically connected to the first conductor 21. The second terminal 33 (the drain terminal if the electronic component 30 is a FET) of the electronic component 30 is electrically connected to the second conductor 22. Note that a plurality of the first conductors 21 or the second conductors 22 are used in some cases in accordance with the number of electronic components 30. In the present embodiment, two second conductors 22 are provided sandwiching the first conductor 21. Note that a heat dissipation structure is preferably arranged on the conductive member 20 on the side opposite to the substrate 10. If such a heat dissipation structure is provided, performance of dissipating heat generated in the substrate 10 or the conductive member 20 increases. A configuration may also be adopted in which the heat dissipation performance of the conductive member 20 is increased without providing such a separate heat dissipation structure. For example, a configuration may also be adopted in which fins or the like is formed on a surface that is opposite to the substrate 10 of the conductive member 20.

The electronic component 30 is mounted so that it reaches from the first conductor 21 to the second conductor 22. Specifically, the electronic component is mounted as follows. The substrate 10 is provided with an opening 11 through which the electronic component 30 can pass. The electronic component 30 (the main body 31) in the present embodiment is placed on the conductive member 20 through this opening 11. Because the first terminal 32 and the third terminal 34 are located on one side of the main body 31 and the second terminal 33 is located on the other side of the main body 31, the electronic component 30 (the main body 31) is placed on the conductive member 20 so that it reaches from the first conductor 21 to the second conductors 22 (a space between the first conductor 21 and the second conductor 22 being located between the second terminal 33 and the first terminal 32 and the third terminal 34). The first terminal 32 is then connected to the first conductor 21, and the second terminal 33 is connected to the second conductor 22 (see FIGS. 3, 4, for example).

The third terminal 34 is located on the same side as the first terminal 32. In the present embodiment, the first conductor 21 of the conductive member 20 is provided with a notch 213 obtained by generously cutting out a portion of the first conductor 21, and this notch 213 and the third terminal 34 overlap with each other in the height direction. Specifically, side edges of the first conductor 21 and the second conductor 22 that face each other are located approximately in parallel to each other, and a portion of the first conductor 21 is cut out in a direction away from the second conductor 22 (forming a recessed shape in plan view), and the notch 213, which is the cut out portion, and the third terminal 34 overlap with each other. That is, the conductive member 20 (the first conductor 21) does not overlap with the third terminal 34 in the height direction, and the third terminal 34 is not covered by the conductive member 20, but is exposed (see FIGS. 3, 4, for example). Although the conductive member 20 (the first conductor 21) does not overlap with the entire third terminal 34 in the present embodiment, the conductive member 20 may also overlap with a portion of the third terminal 34, without overlapping with the other portions thereof. As will be described later, the third terminal 34 is electrically connected to the terminal connection portion 12, and thus a structure is preferable in which the third terminal 34 does not overlap with the conductive member 20 at least on the side of the terminal connection portion 12. Note that if such a structure is adopted and a portion of the third terminal 34 overlaps with the conductive member 20 (the first conductor 21), then they are insulated from each other in order to avoid a short circuit.

Also, the other side 10b of the substrate 10 is provided with a terminal connection portion 12 (land) made of an electrically conductive material. This terminal connection portion 12 is electrically connected to the wiring pattern 101 formed on the one side 10a of the substrate 10 (see FIGS. 4, 5(b), for example). Any structure for connection between the terminal connection portion 12 and the wiring pattern 101 may be adopted. For example, it is sufficient if the terminal connection portion 12 and the wiring pattern 101 are connected to each other by a conductive member that passes through a through hole in the substrate 10.

The terminal connection portion 12 in the present embodiment overlaps with the notch 213 formed in the first conductor 21 of the conductive member 20 in the height direction. That is, the conductive member 20 (the first conductor 21) does not overlap in the height direction with not only the third terminal 34 but also does not overlap in the height direction with the terminal connection portion 12. Thus, the terminal connection portion 12 is not covered by the conductive member 20 and is exposed (see FIG. 4 for example). In the present embodiment, nothing obstructs the space between the third terminal 34 and the terminal connection portion 12. That is, the conductive member 20 (the first conductor 21) is not present between the third terminal 34 and the terminal connection portion 12.

In the present embodiment, the third terminal 34 and the terminal connection portion 12 are connected to each other by a lead member 40 made of an electrically conductive material (see FIGS. 4, 5(b), for example). That is, the third terminal 34 and the terminal connection portion 12 are electrically connected by the lead member 40. Furthermore, the terminal connection portion 12 and the wiring pattern 101 (circuit) formed on the one side 10a of the substrate 10, and thus the third terminal 34 is electrically connected to the wiring pattern 101 formed on the one side 10a of the substrate 10 via the terminal connection portion 12.

In this manner, the conductive member 20 does not overlap with the third terminal 34 or the terminal connection portion 12 and nothing obstructs the space located therebetween, and thus, the third terminal 34 and the terminal connection portion 12 can be electrically connected to each other by providing the lead member 40 (by connecting one end of the lead member 40 to the third terminal 34 and connecting the other end to the terminal connection portion 12) on the other side 10b of the substrate 10, forming a bridge between the third terminal 34 and the terminal connection portion 12.

Also, the entire conductive member 20 (the first conductor 21 and the second conductors 22) in the present embodiment overlaps with the substrate 10 in the height direction. In other words, the entire conductive member 20 is located inward of the outer circumferential edge of the substrate 10 (see FIG. 1 for example). Therefore, a range occupied by the circuit assembly 1 of the present embodiment in the surface direction is the same as the size of the substrate 10 in the surface direction. The reason why such a shape can be used will be described later.

The first conductor 21 and the second conductors 22 are respectively provided with electrical connection portions and mechanical connection portions. Hereinafter, an electrical connection portion provided to the first conductor 21 is referred to as “first electrical connection portion 211”, a mechanical connection portion provided to the first conductor 21 is referred to as “first mechanical connection portion 212”, an electrical connection portion provided to the second conductor 22 is referred to as “second electrical connection portion 221”, and a mechanical connection portion provided to the second conductor 22 is referred to as “second mechanical connection portion 222”. In the present embodiment, the electrical connection portions 211 and 221 and the mechanical connection portions 212 and 222 are connected to the other side 10b of the substrate 10 by soldering (see FIG. 1(b) for example).

The one side 10a of the substrate 10 is provided with external connection patterns 102 and 103, which are conductive patterns that are different from the above-described wiring pattern 101 (see FIG. 6 for example). A first external connection pattern 102 and a second external connection pattern 103 are formed as such a conductive pattern. The wiring pattern 101, the first external connection pattern 102, and the second external connection pattern 103 are in an electrically independent state. Ends of the wiring pattern 101, the first external connection pattern 102, and the second external connection pattern 103 are electrically connected to terminals of substrate connectors (not shown). A structure may also be adopted in which the ends of these patterns are collected at a specific site and electrically connected to a terminal of one substrate connector, and a structure may also be adopted in which at least one terminal is electrically connected to a terminal of a substrate connector that is different from the one to which the other ends are connected.

The other side 10b of the substrate 10 is provided with an external connection portion (land) including the fist external connection portion 13 and the second external connection portion 14. The first external connection portion 13 is electrically connected to the first external connection pattern 102 formed on the one side 10a of the substrate 10. Similarly, the second external connection portion 14 is electrically connected to the second external connection pattern 103 formed on the one side 10a of the substrate 10. Any structure for connection between the external connection portions 13 and 14 and the external connection patterns may be adopted. For example, it is sufficient if the external connection portion and the external connection pattern are connected to each other by a conductive member that passes through a through hole in the substrate 10.

The first electrical connection portion 211 is connected to the above-described first external connection portion 13. Similarly, the second electrical connection portion 221 is connected to the above-described second external connection portion 14 (see FIGS. 1(b), 6, for example). That is, the first conductor 21 is electrically connected to the first external connection pattern 102 via the first external connection portion 13. The second conductors 22 are electrically connected to the second external connection patterns 103 via the second external connection portions 14. A pattern for the first external connection portion 13 and a pattern for the second external connection portion 14 can be electrically connected to an external electrical element via the above-described substrate connector. That is, in the present embodiment, the first conductor 21 and the second conductors 22 can be electrically connected to external electrical elements via external connection means provided on the substrate 10 (the external connection portions 13 and 14, the external connection patterns 102 and 103, and the substrate connector (not shown)). Note that the configuration of this external connection means is merely one example, and its structure can be modified as appropriate as long as the structure makes it possible to connect the first conductor 21 and the second conductor 22 to an external electrical element by various electrical constituent elements provided on the substrate 10.

In the present embodiment, both sides of the first electrical connection portion 211 in the first conductor 21 and both sides of the second electrical connection portion 221 in the second conductor 22 are provided with notches (see FIG. 1(b) for example)). Accordingly, a stress produced at a site at which the first electrical connection portion 211 and the first external connection portion 13 are connected, and a stress produced a site at which the second electrical connection portion 221 and the second external connection portion 14 are connected are reduced.

On the other hand, the mechanical connection portions 212 and 222 fix the first conductor 21 and the second conductors 22 to the substrate 10. Thus, the first mechanical connection portions 212 are provided at a plurality of locations along the outer edge of the first conductor 21, and the second mechanical connection portions 222 are provided at a plurality of locations along the outer edge of the second conductors 22. The first mechanical connection portions 212 are connected to a plurality of first fixing portions 15 (lands) provided on the other side 10b of the substrate 10. The second mechanical connection portions 222 are connected to a plurality of second fixing portions 16 (lands) provided on the one side 10a of the substrate 10.

Hereinafter, a preferred method for manufacturing the circuit assembly 1 according to the present embodiment will be described, which will partly overlap with the above description.

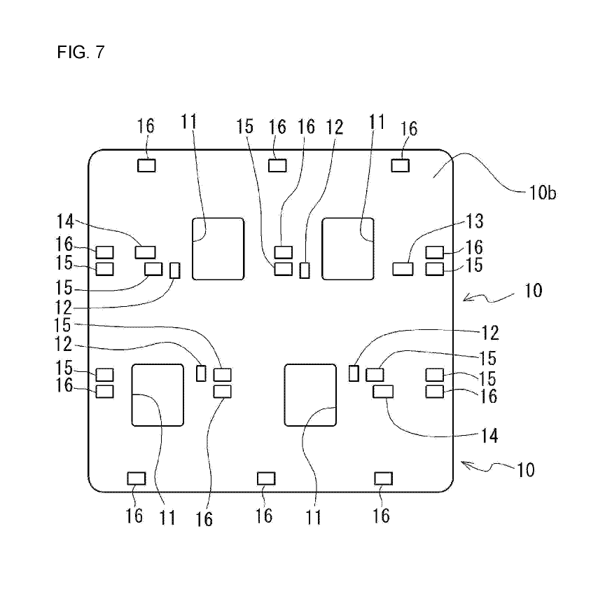

First, the substrate 10 is produced and is provided with the wiring pattern 101, the external connections patterns (the first external connection pattern 102 and the second external connection pattern 103), the openings 11, the terminal connection portions 12, the external connection portions (the first external connection portion 13 and the second external connection portion 14), the fixing portions (the first fixing portion 15 and the second fixing portion 16), and the like (see FIG. 7). A resist 10c (insulating layer) is formed on the other side 10b of the substrate 10. The resist 10c is formed while avoiding sites at which the terminal connection portions 12, the external connection portions 13 and 14, and the fixing portions 15 and 16 are formed. Use of such a resist (solder resist) 10c as the insulating layer makes it possible to reduce the cost for producing the substrate 10 compared to a case where a separate insulating adhesive, sheet, or the like is used. The specific method for producing this substrate 10 may be any method, and thus its description is omitted.

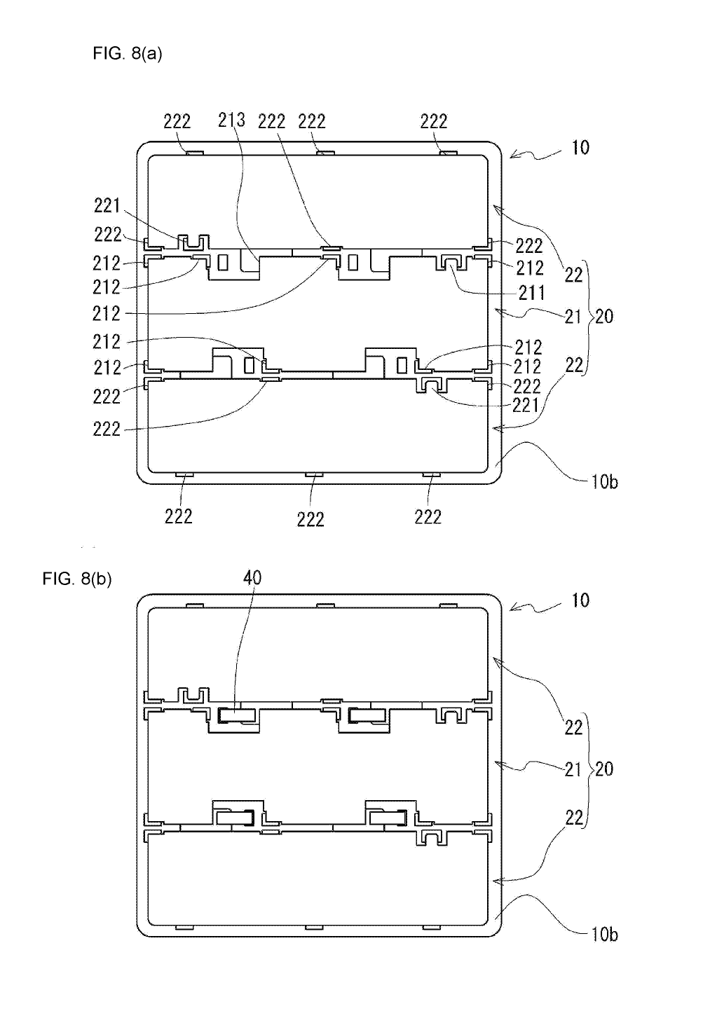

The conductive member 20, that is, the first conductor 21 and the second conductors 22 are placed on the other side 10b of the substrate 10 (see FIG. 8(a)). The first conductor 21 and the second conductors 22, which are plates of the conductive member 20 made of copper or the like, are in a separated state (unjoined state) from the beginning. Along with this, the lead member 40 is placed thereon (see FIG. 8(b)). Note that there is no limitation to the order of placement of the two types of conductors 21 and 22 and the lead member 40. The first conductor 21 is placed thereon such that the first electrical connection portion 211 is located on the first external connection portion 13, and the first mechanical connection portions 212 are located on the corresponding first fixing portions 15. The second conductors 22 are placed thereon such that the second electrical connection portions 221 are located on the second external connection portion 14, and the second mechanical connection portions 222 are located on the corresponding second fixing portions 16. The lead member 40 is placed thereon such that its one side is located on the terminal connection portion 12. The terminal connection portions 12 are not covered by the first conductor 21 and are exposed due to the notches 213 formed in the first conductor 21, and thus the lead member 40 can be placed such that the one side of the lead member 40 is located on the terminal connection portion 12. All of the first conductor 21, the second conductors 22, and the lead members 40 that are placed in this manner overlap with the substrate 10 in the height direction. That is, all of them are located inward of the outer circumferential edge of the substrate 10. Note that a jig or the like for positioning the first conductor 21, the second conductors 22, and the lead members 40 with respect to the substrate 10 may be used until a conductive member connection step and a lead member connection step below are complete.

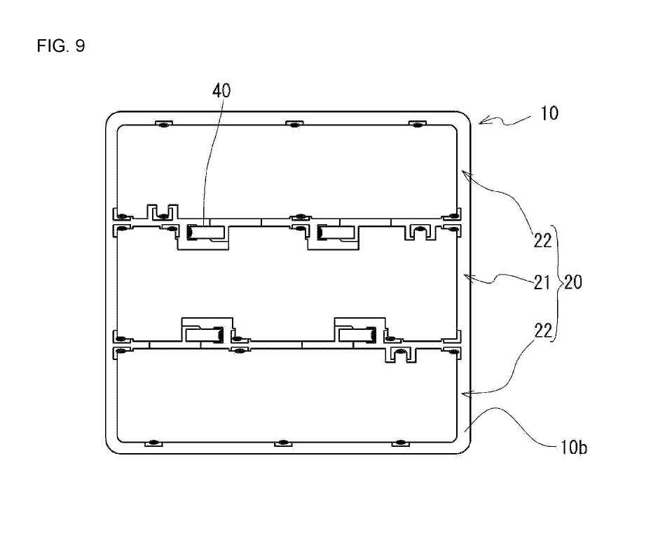

After these members are placed, predetermined regions of the members are connected to predetermined regions in the substrate 10 (see FIG. 9). In the first conductor 21, the first electrical connection portion 211 is connected to the first external connection portion 13, the first mechanical connection portions 212 are connected to the corresponding first fixing portions 15, and in the second conductor 22, the second electrical connection portion 221 is connected to the second external connection portion 14, and the second mechanical connection portions 222 are connected to the corresponding second fixing portions 16 (conductive member connection step). Accordingly, the first conductor 21 and the second conductors 22 are mechanically connected to the substrate 10, and are electrically connected to the above-described external connection means provided on the substrate 10. One end of the lead member 40 is connected to the terminal connection portion 12 (lead member connection step). That is, the lead member 40 is electrically connected to the wiring pattern 101 via the terminal connection portion 12. These connections can be made by soldering (solder with adhesive). For example, by applying solder to the terminal connection portion 12, the external connection portions 13 and 14, and the fixing portions 15 and 16 on the one side 10a of the substrate 10 in advance, all of the connections can be made at once in a reflow soldering step. That is, the conductive member connection step and the lead member connection step can be performed in the same step, which thus leads to a reduction in the manufacturing cost.

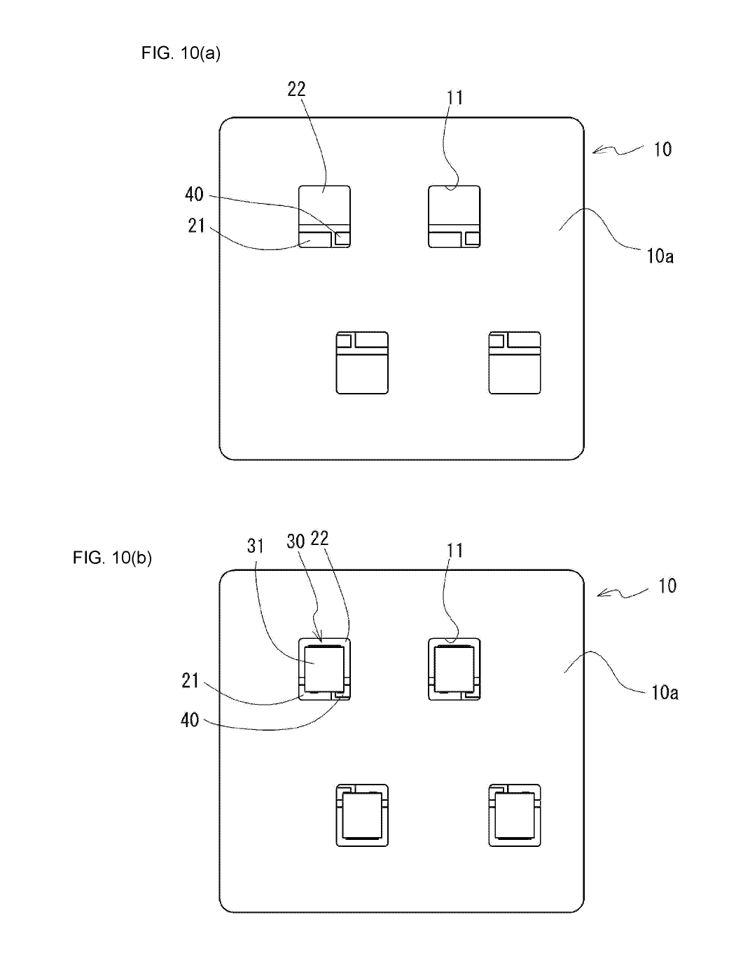

Thereafter, the electronic components 30 are mounted. Specifically, the electronic components 30 are placed on the conductive member 20 and the lead member 40 through the opening 11 formed in the substrate 10, from the one side 10a of the substrate 10 (see FIG. 10(a)) in “a combination of the substrate 10, the conductive member 20, and the lead member 40” obtained through the conductive member connection step and the lead member connection step (see FIG. 10(b)). The electronic components 30 are placed thereon such that the first terminals 32 are located on the first conductor 21, the second terminals 33 are located on the second conductors 22, and the third terminals 34 are located on the lead member 40, and the terminals are connected to the members by soldering or the like, and the terminals are connected to the members by soldering or the like (electronic component mounting step).

The circuit assembly 1 (see FIG. 1) according to the present embodiment can be obtained through the steps above. Note that a conventional circuit assembly needs a step of separating portions that join the conductors 21 and 22 of the conductive member 20. Because portions located outward of the outer edge of the substrate 10 are separated, a portion of the conductive member 20 protrudes from the outer edge of the substrate 10. On the other hand, the circuit assembly 1 according to the present embodiment is in a state in which the entire conductive member 20 (the first conductor 21 and the second conductors 22) overlaps with the substrate 10, and has no portion protruding from the outer edge of the substrate 10. Also, the lead member 40 overlaps with the substrate 10. Therefore, a range occupied by the circuit assembly 1 in the surface direction is the same as the size of the substrate 10 in the surface direction. Thus, the size of the circuit assembly in the surface direction can be further reduced compared to a conventional circuit assembly.

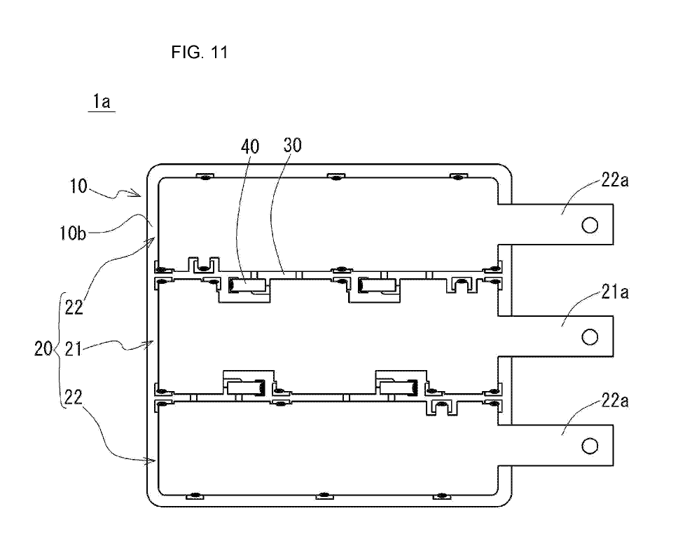

Hereinafter, a modification of the circuit assembly 1 according to the present embodiment will be described. Although it was explained that in the circuit assembly 1 according to the above-described embodiment, the entire conductive member 20 overlaps with the substrate 10 in the height direction, as in a circuit assembly la according to a modification shown in FIG. 11, if the conductive member 20 (the first conductor 21 and the second conductors 22) has portions that are connected to external electrical elements, at least one of the portions (the portion provided to the first conductor 21 is referred to as “terminal portion 21a” and the portion provided to the second conductor 22 is referred to as “terminal portion 22a” in some cases, hereinafter) may also be located outward of the outer edge of the substrate 10 (do not necessarily overlap with the substrate 10 in the height direction. Note that the shape of the terminal portions 21a and 22a is set in correspondence with an external electrical element as appropriate, and thus it may be any arbitrary shape. Note that the circuit assembly 1 according to the above-described embodiment has a configuration in which the substrate 10 is provided with an external connection means for electrically connecting the conductors 21 and 22 to an external electrical element, and thus the conductors 21 and 22 can be configured to be located inward of the outer edge of the substrate 10.

As in the present modification, even though at least one of the terminal portions 21a and 22a of the conductors 21 and 22 is located outward of the outer edge of the substrate 10, the other portions overlap with the substrate 10, and thus the size of the circuit assembly la in the surface direction can be further reduced compared to a conventional circuit assembly. Note that the circuit assembly la according to the present modification will be also produced in a manufacturing step that is similar to that for the circuit assembly 1 according to the above-described embodiment.

Although an embodiment of the present invention was described in detail above, the present invention is not merely limited to the above-described embodiment, and it will be appreciated that various modifications can be made without departing from the gist of the present invention.

1. A circuit assembly comprising:
a substrate provided with a wiring pattern on one side of the substrate;
a conductive member that is fixed to the other side of the substrate and includes a first conductor and a second conductor that are fixed to the other side of the substrate in a separated state; and
an electronic component that includes a first terminal that is electrically connected to the fist conductor of the conductive member, a second terminal that is electrically connected to the second conductor of the conductive member, and a third terminal that is electrically connected to the wiring pattern that is formed on the substrate,
wherein the conductive member overlaps with the substrate, but not at a portion that is to be connected to an external electrical element,
the other side of the substrate is provided with a terminal connection portion that is joined to the wiring pattern such that the terminal connection portion does not overlap with the conductive member, and
the third terminal of the electronic component is electrically connected to the terminal connection portion via a lead member.

2. The circuit assembly according to claim 1,
wherein the substrate is provided with an external connection means for electrically connecting the conductive member to an external electrical element,
the conductive member is provided with an electrical connection portion that is electrically connected to the external connection means, and
the entire conductive member overlaps with the substrate.

3. The circuit assembly according to claim 1,
wherein the conductive member is provided with a mechanical connection portion that is fixed to the substrate.

4. A method for manufacturing a circuit assembly, comprising:
a conductive member connection step of fixing, to a substrate, a conductive member including a first conductor and a second conductor in a state in which the first conductor and the second conductor are separated from each other, the substrate being provided with a wiring pattern on one side of the substrate and being provided with an insulating layer on the other side, the conductive member being fixed to the other side of the substrate such that the conductive member overlaps with the substrate, but not at a portion that is to be connected to an external electrical element;
wherein the other side of the substrate is provided with a terminal connection portion that is joined to the wiring pattern such that the terminal connection portion does not overlap with the conductive member,
the method further comprising:
a lead member connection step of connecting a lead member to the terminal connection portion on the other side of the substrate, the conductive member connection step and the lead member connection step being performed simultaneously; and
an electronic component mounting step of mounting an electronic component having a plurality of terminals, electrically connecting a first terminal of the electronic component to the first conductor, electrically connecting a second terminal of the electronic component to the second conductor, and electrically connecting a third terminal of the electronic component to the wiring pattern formed on the substrate, and
in the electronic component mounting step, the third terminal of the electronic component is connected to the lead member.

5-8. (canceled)

9. The circuit assembly according to claim 2, wherein the conductive member is provided with a mechanical connection portion that is fixed to the substrate.
